(19) United States
(12) Patent Application Publication
(10) Pub. No.: US 2014/0116759 A1
(43) Pub. Date: May 1, 2014

(54) PRINTED WIRING BOARD AND METHOD FOR MANUFACTURING PRINTED WIRING BOARD

(71) Applicant: IBIDEN CO., LTD., Ogaki-shi (JP)

(72) Inventor: Satoshi WATANABE, Ogaki-shi (JP)

(73) Assignee: IBIDEN CO., LTD., Ogaki-shi (JP)

(21) Appl. No.: 14/064,401

(22) Filed: Oct. 28, 2013

(30) Foreign Application Priority Data
Oct. 26, 2012 (JP) 2012-236213

(51) Int. Cl. H05K 1/05; H05K 3/02

(52) U.S. Cl. CPC H05K 1/056; H05K 3/02
USPC 174/255; 156/247; 156/248

(57) ABSTRACT

A method for manufacturing a printed wiring board includes fixing a lower metal foil on a support plate, forming a lower insulating layer on the lower metal foil, laminating a core metal layer on the lower insulating layer, patterning the core metal layer such that the core metal layer is formed into a core conductive layer, forming an upper insulating layer on the core conductive layer and lower insulating layer, laminating an upper metal foil on the upper insulating layer, removing the plate from the lower foil such that a core substrate including the lower metal foil, lower insulating layer, core conductive layer, upper insulating layer and upper metal foil is formed, and forming on the core substrate a buildup layer including an insulating layer and a conductive layer. The core metal layer has a thickness which is set to be greater than thicknesses of the lower and upper foils.

### CROSS-REFERENCE TO RELATED APPLICATIONS

The present application is based upon and claims the benefit of priority from U.S. Application No. 2012-236213, filed Oct. 26, 2012, the entire contents of which are incorporated herein by reference.

### BACKGROUND OF THE INVENTION

1. Field of the Invention

The present invention relates to a method for manufacturing a buildup multilayer printed wiring board successively laminated using a support plate, and to the printed wiring board.

2. Description of Background Art

JP 2004-193186 A describes a metal-core printed wiring board, in which a metal plate is provided in the core substrate. In the printed wiring board, an opening is formed in the metal plate to pass a through-hole conductor, resin is filled in the opening and a through-hole conductor is formed in the filled resin so that insulation is maintained between the metal plate and the through-hole conductor. The entire contents of this publication are incorporated herein by reference.

### SUMMARY OF THE INVENTION

According to one aspect of the present invention, a method for manufacturing a printed wiring board includes fixing a lower metal foil on a support plate, forming a lower insulating layer on the lower metal foil, laminating a core metal layer on the lower insulating layer, patterning the core metal layer such that the core metal layer is formed into a core conductive layer, forming an upper insulating layer on the core conductive layer and lower insulating layer, laminating an upper metal foil on the upper insulating layer, removing the support plate from the lower metal foil such that a core substrate including the lower metal foil, the lower insulating layer, the core conductive layer, the upper insulating layer and the upper metal foil is formed, and forming on the core substrate a buildup layer including an insulating layer and a conductive layer. The core metal layer has a thickness which is set to be greater than a thickness of the lower metal foil and a thickness of the upper metal foil.

According to another aspect of the present invention, a printed wiring board includes a core substrate, and a buildup layer formed on the core substrate and including an insulating layer and a conductive layer. The core substrate includes a core conductive layer, an upper insulating layer formed on an upper surface of the core conductive layer, an upper conductive layer formed on the upper insulating layer, a lower insulating layer formed on a lower surface of the core conductive layer, a lower conductive layer formed on the lower insulating layer, an upper via conductor formed in the upper insulating layer and connecting the core conductive layer and the upper conductive layer, and a lower via conductor formed in the lower insulating layer and connecting the core conductive layer and the lower conductive layer, and the core conductive layer has a thickness which is greater than a thickness of the lower conductive layer and a thickness of the upper conductive layer.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIGS. 1A, 1B and 1C are process drawings illustrating a method for manufacturing a printed wiring board according to a first embodiment of the present invention;

FIGS. 2A, 2B and 2C are process drawings illustrating the method for manufacturing a printed wiring board according to the first embodiment;

FIGS. 3A and 3B are process drawings illustrating the method for manufacturing a printed wiring board according to the first embodiment;

FIGS. 4A and 4B are process drawings illustrating the method for manufacturing a printed wiring board according to the first embodiment;

FIGS. 5A and 5B are process drawings illustrating the method for manufacturing a printed wiring board according to the first embodiment;

FIGS. 6A, 6B and 6C are process drawings illustrating the method for manufacturing a printed wiring board according to the first embodiment;

FIGS. 7A, 7B and 7C are process drawings illustrating the method for manufacturing a printed wiring board according to the first embodiment;

FIGS. 8A, 8B and 8C are process drawings illustrating the method for manufacturing a printed wiring board according to the first embodiment;

FIGS. 9A and 9B are process drawings illustrating the method for manufacturing a printed wiring board according to the first embodiment;

FIGS. 10A and 10B are process drawings illustrating the method for manufacturing a printed wiring board according to the first embodiment;

FIGS. 11A and 11B are process drawings illustrating a method for manufacturing a printed wiring board according to a second embodiment of the invention;

FIGS. 12A, 12B, 12C and 12D are process drawings illustrating the method for manufacturing a printed wiring board according to the second embodiment; and

FIG. 13 is a cross-sectional view of a printed wiring board according to a third embodiment of the invention.

### DETAILED DESCRIPTION OF THE EMBODIMENTS

The embodiments will now be described with reference to the accompanying drawings, wherein like reference numerals designate corresponding or identical elements throughout the various drawings.

### First Embodiment

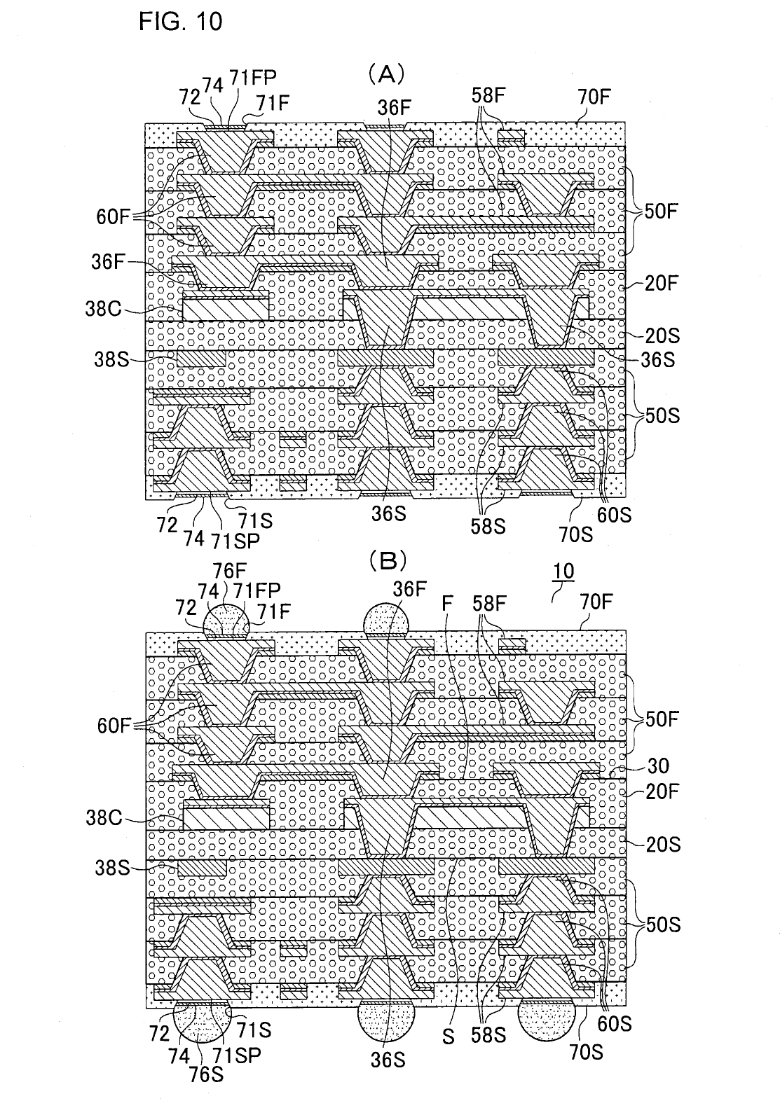

FIG. 10B illustrates a printed wiring board according to the first embodiment. A printed wiring board 10 is provided with a core substrate 30 including an upper insulating layer (20F) and a lower insulating layer (20S).

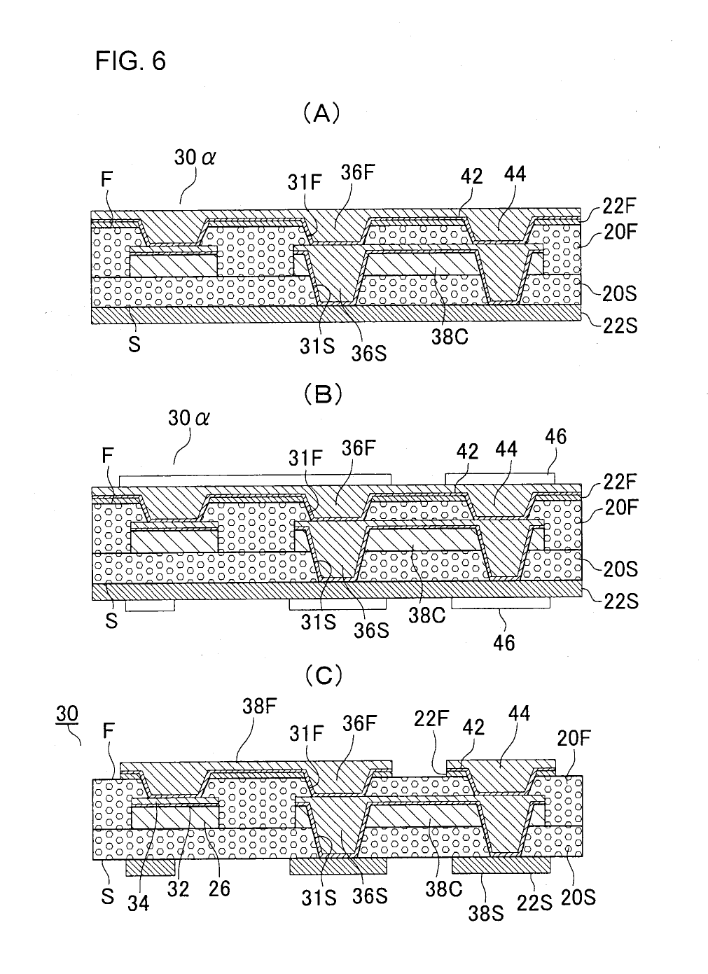

FIG. 6C illustrates the core substrate 30. An upper conductive layer (38F) is formed on the upper insulating layer (20F), and a lower conductive layer (38S) is formed beneath the lower insulating layer (20S). A core conductive layer (38C) is formed between the upper and lower insulating layers. In an opening (31F) of the upper insulating layer (20F), an upper via conductor (36F) is formed for connecting the upper conductive layer (38F) and the core conductive layer (38C). In an opening (31S) of the lower insulating layer (20S), a lower via conductor (36S) is formed for connecting the lower conductive layer (38S) and the core conductive layer (38C). The lower conductive layer (38S) is formed by patterning a lower metal foil (22S) laminated on the lower insulating layer (20S). The core conductive layer (38C) is formed by patterning a core metal layer 26 and an electroless plating film 32 and an electrolytic plating film 34, which are formed on the core metal layer 26. The upper conductive layer (38F) is formed by patterning an upper metal foil (22F) and an electroless plating film 42 and an electrolytic plating film 44, which are formed on the upper metal foil (22F). The upper via conductor (36F) and the lower via conductor (36S) are both formed in a tapered shape having a diameter decreasing downward.

In the printed wiring board 10 of the first embodiment, three layers each of a first conductive layer (58F) and a first insulating layer (50F) with a first via conductor (60F) are built up on the first surface (F) of the core substrate 30 as shown in FIG. 10B. On the second surface (S) of the core substrate 30, three layers each of a second conductive layer (58S) and a second insulating layer (50S) with second via conductor (60S) are built up. A solder-resist layer (70F) is formed on the uppermost first insulating layer (50F), and a solder bump (76F) is formed in an opening (71F) provided in the solder-resist layer (70F). A solder-resist layer (70S) is formed on the lowermost second insulating layer (50S), and a solder bump (76S) is formed in an opening (71S) formed in the solder-resist layer (70S).

Since a metal core structure having the core conductive layer (38C) in the center of the core substrate 30 is employed in the printed wiring board 10 according to the first embodiment, warping is suppressed due to the rigidity of the thick core conductive layer (38C), and the demand for thinner boards can be met. Multiple via lands, being electrically independent of each other, are arranged in the core conductive layer (38C), flexibility in wiring design is enhanced, and a highly integrated wiring board is also achieved. Since the core substrate 30 is triple-layered with the core conductive layer (38C), the lower conductive layer (38S) and the upper conductive layer (38F), even though buildup layers (conductive layers) are provided symmetrically on the upper and lower sides of the core substrate, a printed wiring board having an odd number of conductive layers is achieved.

### Manufacturing Method of First Embodiment

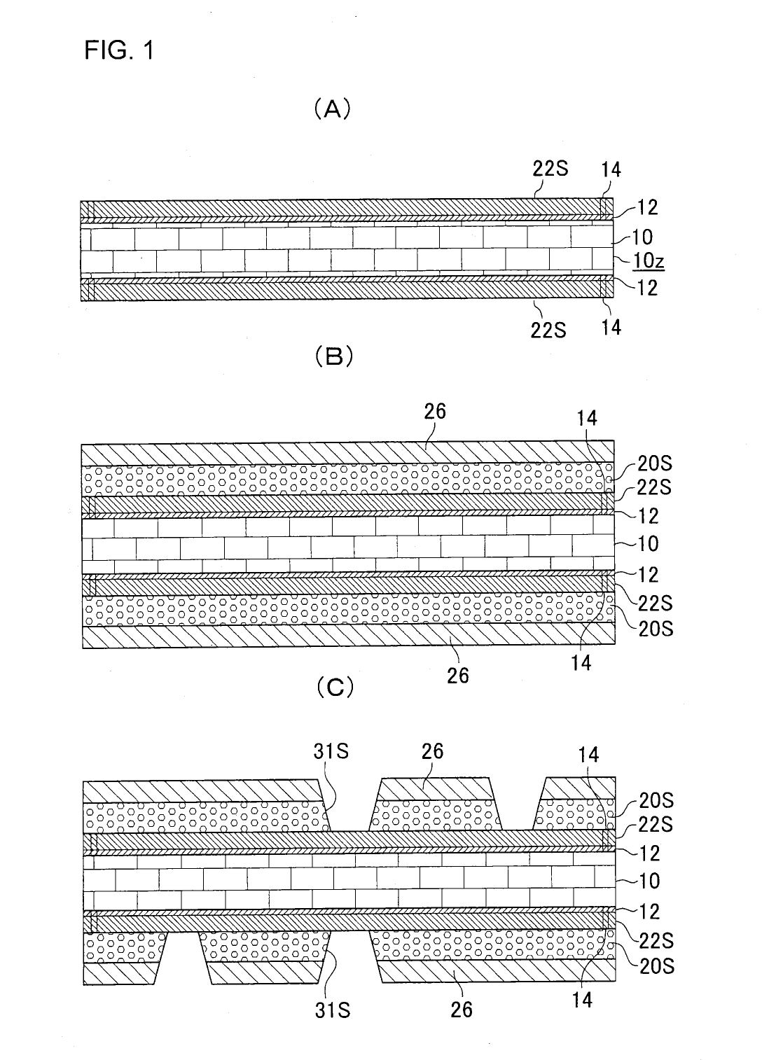

The method for manufacturing the printed wiring board 10 according to the first embodiment is illustrated in FIGS. 1A, 1B and 1C to FIGS. 10A and 10B.

(1) A support plate 10 is prepared. For example, the support plate 10 is a copper-clad laminate (double-sided copper-clad laminate) including an insulating base material (10z) and copper foils 12 laminated on both surfaces of the insulating base material (10z). The support plate 10 has a first surface and a second surface opposite the first surface. A lower-layer metal foil (first metal foil) (22S) is laminated on the first surface of the support plate 10. The metal foil (22S) is, for example, copper foil, and its thickness is 25 μm. The support plate 10 and the metal foil (22S) are fixed in the outer periphery. The copper-clad laminate and the metal foil are bonded using ultrasonic welding. The support plate 10 and the metal foils (22S) are bonded at a fixing portion 14.

The fixing portion 14 is formed in a frame-like shape having a width of several mm (refer to FIG. 1A). The metal foil (22S) has a matte surface (roughened surface), and is laminated on the support plate 10 so that the matte surface and the support substrate 10 do not face each other.

(2) On the lower-layer metal foil (22S), a B-stage resin film is laminated, and the core metal layer 26 is further laminated (refer to FIG. 1B). The thickness of the core metal layer 26 is 36 μm. The matte surface of the lower-layer metal foil (22S) faces the lower insulating layer. Then, the resin film is cured to form the lower insulating layer (20S) on the support plate 10. The lower insulating layer (20S) contains either or both of a reinforcing material and inorganic particles. Examples of the reinforcing material include glass cloth, aramid fibers and glass fibers. The glass cloth is preferred. Examples of the inorganic particles include particles including silica, alumina or a hydroxide. Examples of the hydroxide include a metal hydroxide such as an aluminum hydroxide, magnesium hydroxide, calcium hydroxide and barium hydroxide. Hydroxides produce water when decomposed by heat. Therefore, a hydroxide is thought to be capable of robbing heat from the material forming the insulating layer. That is, it is thought that the performance of a laser may be enhanced by the lower insulating layer (20S) containing a hydroxide. The lower insulating layer (20S) has a first surface and a second surface opposite the first surface, and the second surface faces the matte surface of the metal foil (22S). The lower insulating layer (20S) is formed on the support plate 10. In the first embodiment, the lower insulating layer (20S) is laminated on the support plate 10 with the metal foil (22S) interposed therebetween.

(3) The first surface of the lower insulating layer (20S) is irradiated with laser, and the lower opening (31S) reaching the lower metal foil (22S) is thereby formed in the lower insulating layer (20S) (refer to FIG. 1C). The lower opening (31S) is tapered from the first surface of the lower insulating layer (20S) toward the lower metal foil (22S).

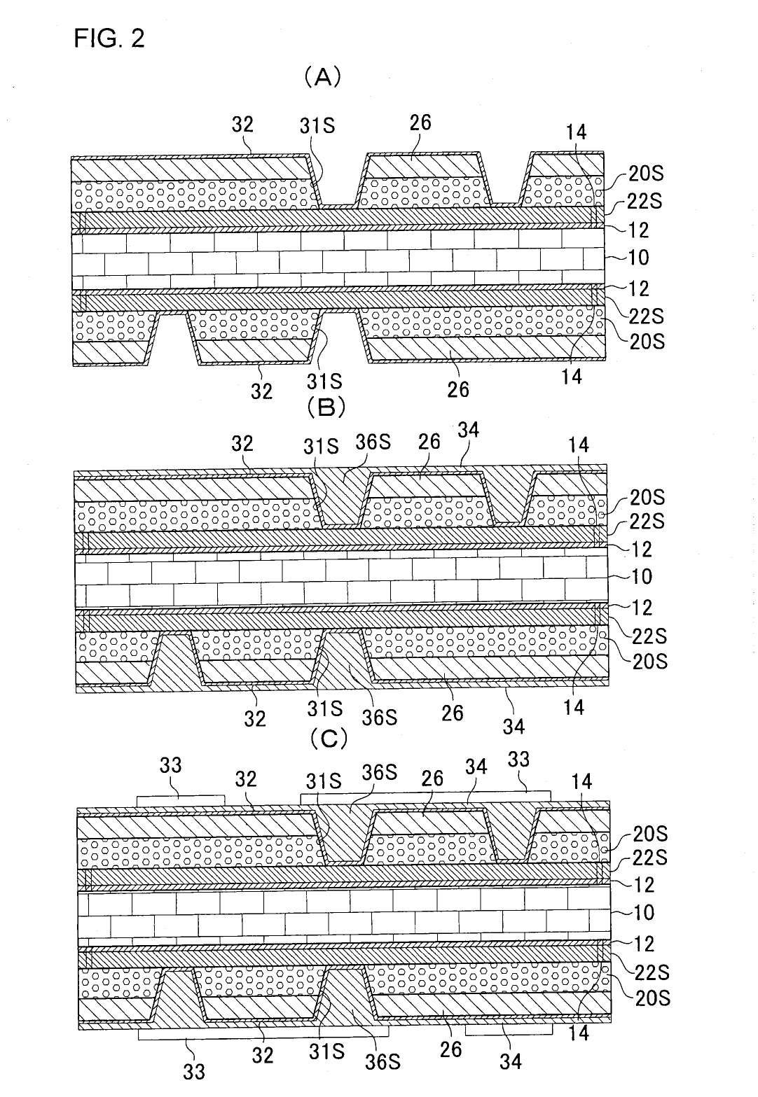

(4) The electroless plating film 32 is formed on the lower metal foil (22S) and on the inner wall of the lower opening (31S) (refer to FIG. 2A).

(5) The electrolytic plating film 34 is formed on the electroless plating film 32 using the electroless plating film 32 as a seed layer. The lower opening (31S) is filled with the electrolytic plating film 34, and the electrolytic plating film 34 is provided on the electroless plating film 32 formed on the lower metal foil (22S) (refer to FIG. 2B).

(6) An etching resist 33 with a predetermined pattern is formed on the electrolytic plating film 34 (refer to FIG. 2C).

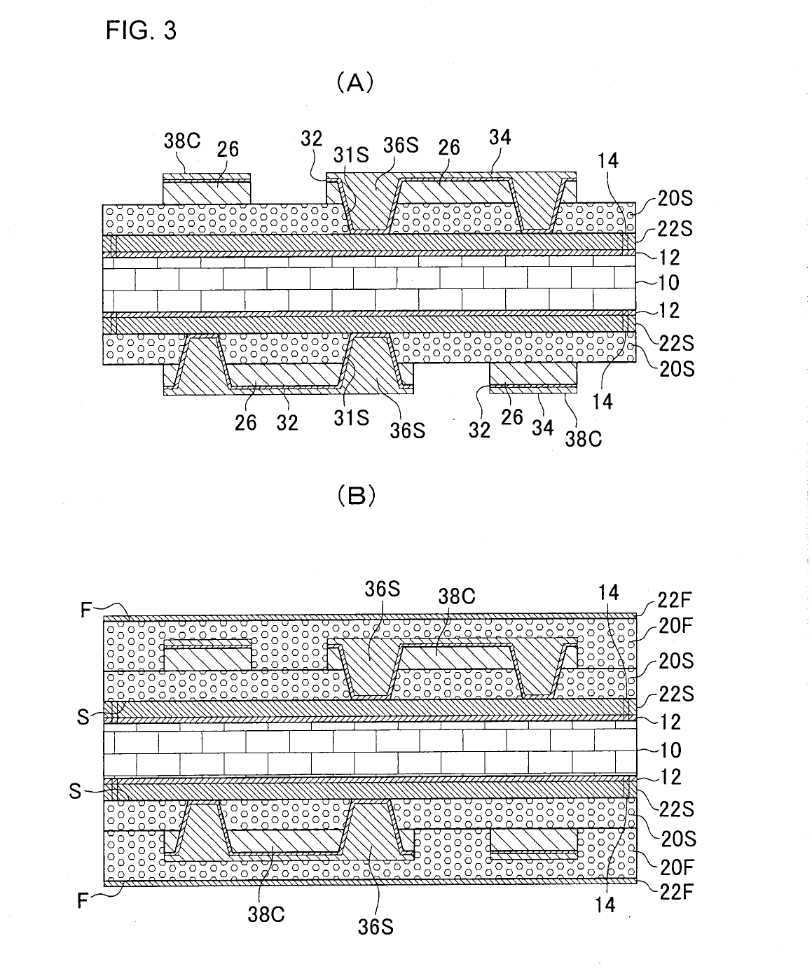

(7) From the area where the etching resist 33 is not formed, the electrolytic plating film 34, the electroless plating film 32 and the core metal layer 26 are removed by etching, and the etching resist 33 is removed. Accordingly, the lower via conductor (36S) is formed in the lower opening (31S), and the core conductive layer (38C), which is made up of the electrolytic plating film 34, the electroless plating film 32 and the core metal layer 26, is formed on the first surface of the lower insulating layer (20S) (refer to FIG. 3A). The lower via conductor (36S) is tapered from the first surface of the lower insulating layer (20S) toward the lower metal foil (22S).

(8) The upper insulating layer (20F) and the upper metal foil (22F) are formed on the first surface of the lower insulating layer (20S) and the core conductive layer (38C) (refer to FIG. 3B). The upper insulating layer (20F) includes a reinforcing material and inorganic particles, the same as in the lower insulating layer (20S). The upper metal foil (22F) is, for example, a copper foil the same as the lower metal foil (22S), and the thickness is 9 μm.

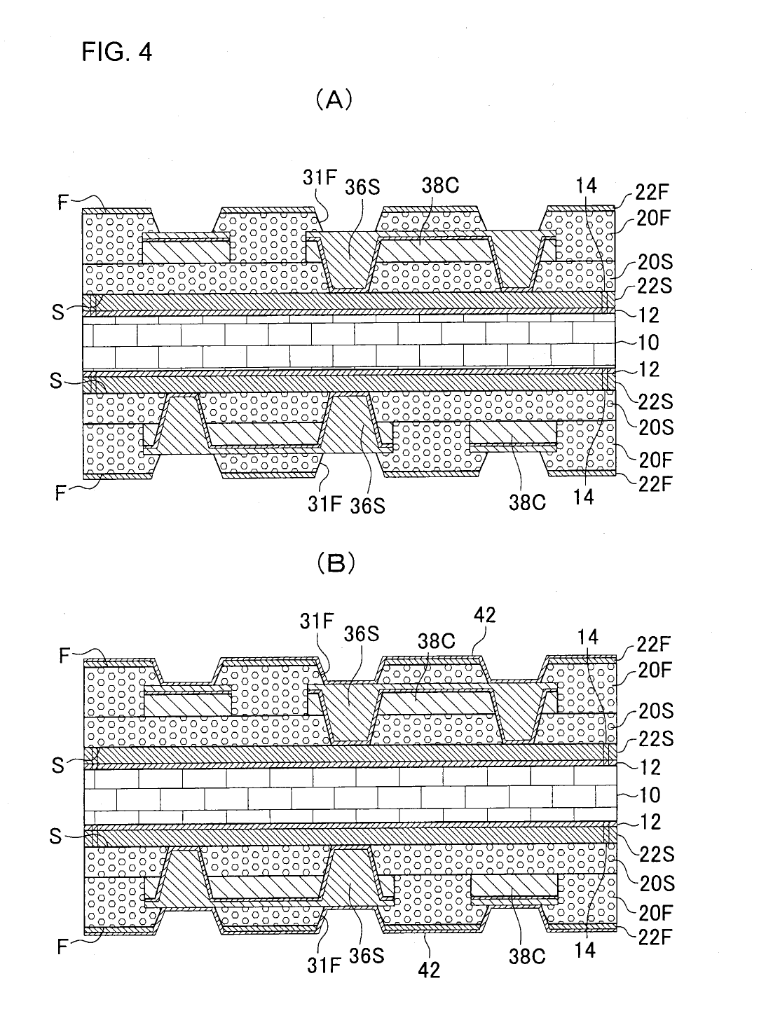

(9) The first surface of the upper insulating layer (20F) is irradiated with laser, and the upper opening (31F) reaching the core conductive layer (38C) is thereby formed in the upper insulating layer (20F) (refer to FIG. 4A).

(10) The electroless plating film 42 is formed on the upper metal foil (22F) and on the inner wall of the upper opening (31F) (refer to FIG. 4B).

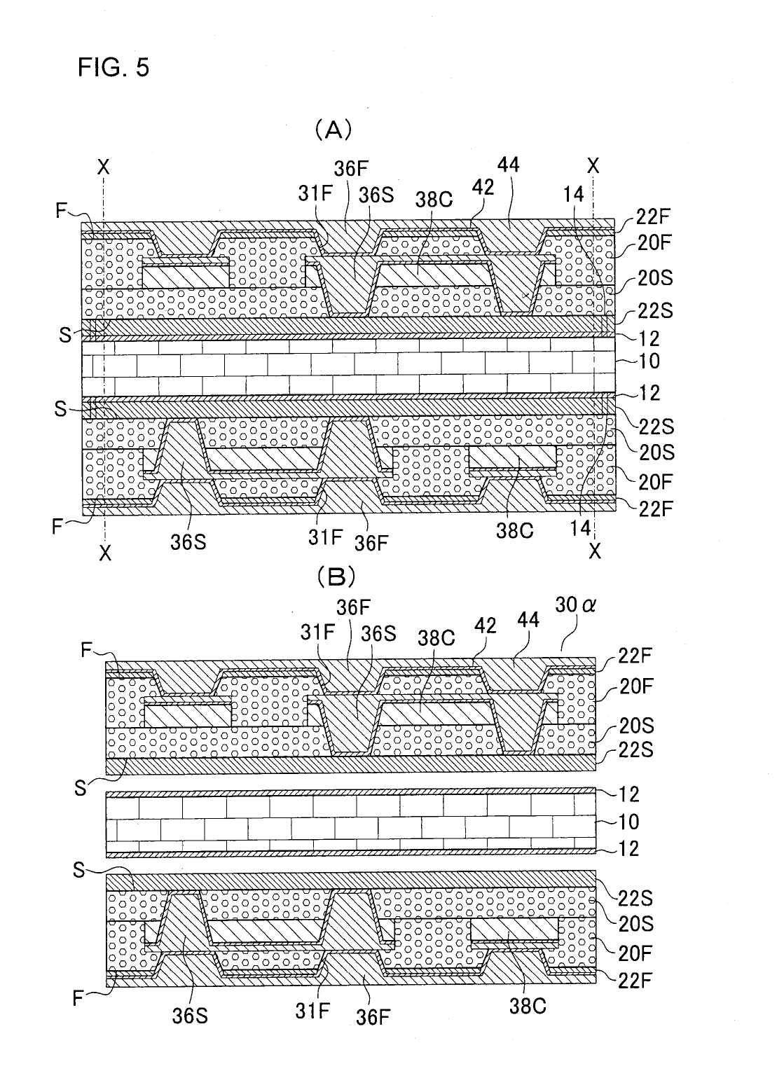

(11) The electrolytic plating film 44 is formed on the electroless plating film 42 using the electroless plating film 42 as a seed layer. The upper opening (31F) is filled with the electrolytic plating film 44, and the electrolytic plating film 44 is provided on the electroless plating film 42 formed on the upper metal foil (22F) (refer to FIG. 5A). At this time, the total thickness of the upper metal foil (22F), the electroless plating film 42 and the electrolytic plating film 44 becomes substantially equal to the thickness of the lower metal foil (22S).

(12) Intermediate portions sandwiching the support plate 10 are cut along lines (X-X) in FIG. 5A. The cut line is inside the fixing portion 14. The intermediate portions (30α) are separated from the support plate 10 (refer to FIG. 5B, FIG. 6A).

(13) Etching resists 46 each having a predetermined pattern are formed on the first-surface (F) side electrolytic plating film 44 and on the second-surface (S) side lower metal foil (22S), respectively (refer to FIG. 6B).

(14) The electrolytic plating film 44, the electroless plating film 42 and the upper metal foil (22F) in the area on the side of the first surface (F) where the etching resist 46 is not formed, and the lower metal foil (22S) in the area on the side of the second surface (S) where the etching resist 46 is not formed, are removed by etching. Then, the etching resists 46 are removed, and the upper conductive layer (38F) including the electroplating film 44, the electroless plating film 42 and the upper metal foil (22F) is formed on the first surface (F), while the lower conductive layer (38S) including the lower metal foil (22S) is also formed on the second surface (S). The core substrate 30 is thereby completed (refer to FIG. 6C).

Since an intermediate substrate has two insulating layers sandwiching a thick core conductive layer and upper and lower conductive layers, the intermediate substrate is fabricated without a support plate. Although the thickness of each of the insulating layer and the upper and lower conductive layers is thin, the intermediate substrate is fabricated without a support plate.

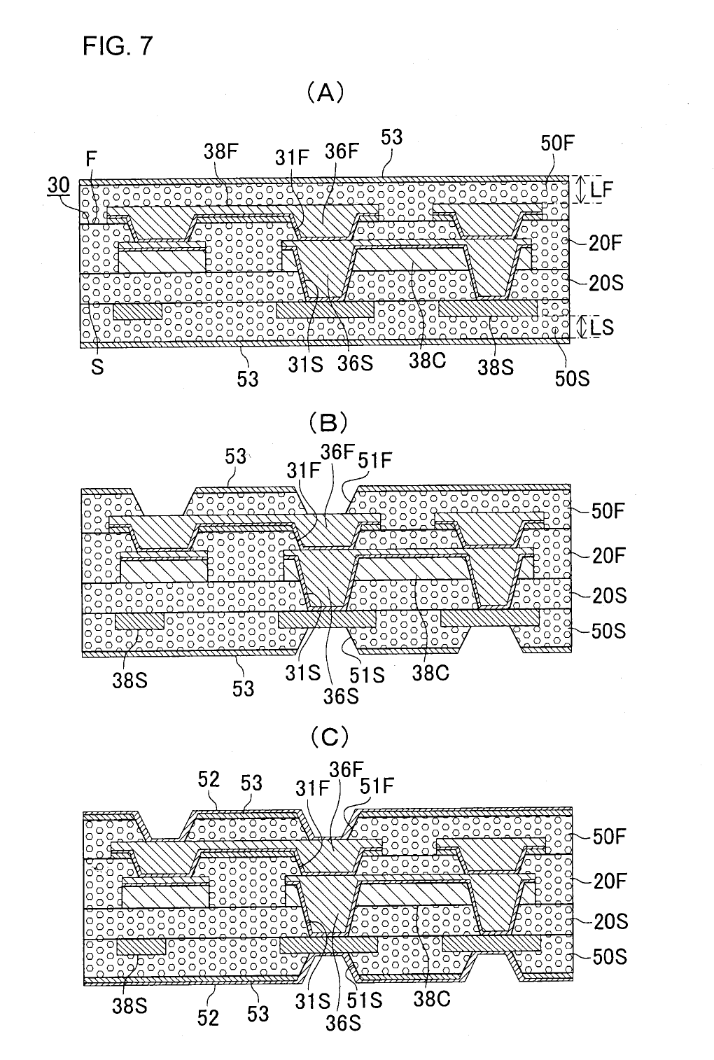

(15) The first insulating layer (50F) and a metal foil 53 are formed on the first surface (F) of the core substrate 30, and the second insulating layer (50S) and the metal foil 53 are formed on the second surface (S) (refer to FIG. 7A). The first insulating layer (50F) is formed on the first surface of the upper insulating layer (20F) and the upper conductive layer (38F). The second insulating layer (50S) is formed on the second surface of the lower insulating layer (20S) and the lower conductive layer (38S). The thickness of each insulating layer is 10 μm to 35 μm. The metal foil 53 is, for example, a copper foil the same as the upper and lower metal foils, and the thickness is 9 μm. The thicknesses (LF, LS) of the insulating layers (50F, 50S) are respectively the distance from the top surface of the conductive layer to the top surface of the insulating layer. The first insulating layer (50F) and the second insulating layer (50S) each contain inorganic particles or contain both inorganic particles and a reinforcing material, and first and second insulation layers are preferred to have the same thickness and material as those of the upper and lower insulating layers (20F, 20S).

(16) Next, a first opening (51F) and a second opening (51S) for via conductors are formed by CO2 gas laser in the first insulating layer (50F) and the second insulating layer (50S), respectively (refer to FIG. 7B).

(17) An electroless plating film 52 is formed on each of the first insulating layer (50F) and the second insulating layer (50S), and in each of the first opening (51F) and the second opening (51S (refer to FIG. 7C).

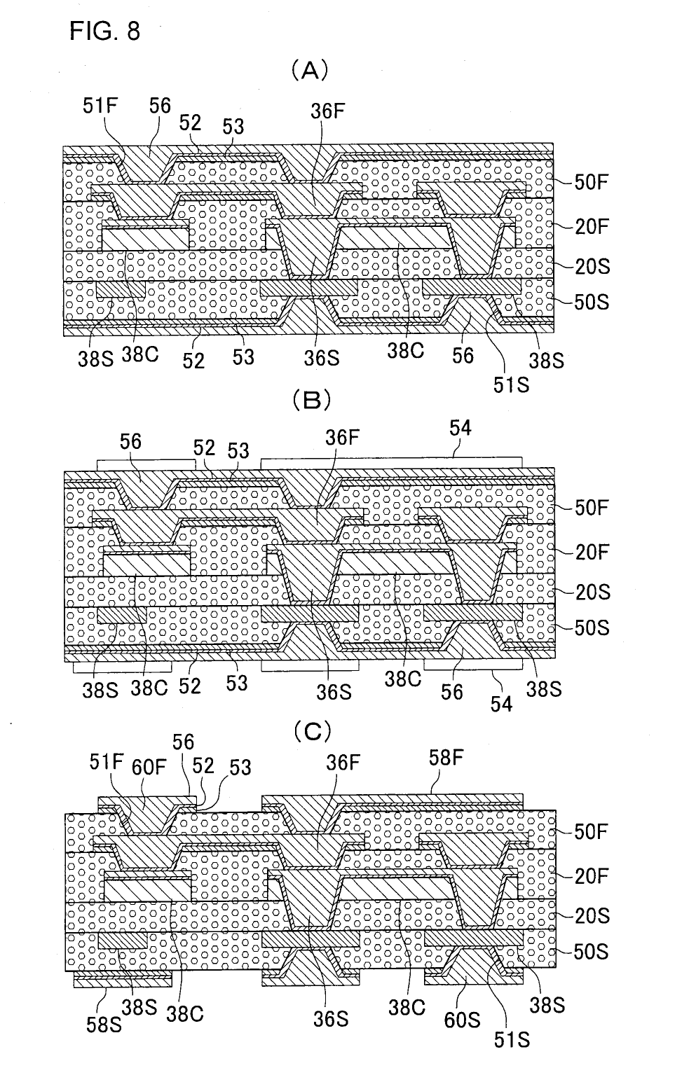

(18) An electrolytic plating film 56 is formed on the electroless plating film 52 using the electroless plating film 52 as a seed layer. The first opening (51F) and the second opening (51S) are filled with the electrolytic plating film 56, and the electrolytic plating film 56 is provided on the electroless plating film 52 formed on the metal foil 53 (refer to FIG. 8A).

(19) On the electrolytic plating film 56, an etching resist 54 having a predetermined pattern is formed (refer to FIG. 8B).

(20) From the area where the etching resist 54 is not formed, the electrolytic plating film 56, the electroless plating film 52 and the metal foil 53 are removed by etching, and the etching resist 54 is removed. Accordingly, the first via conductor (60F) is formed in the first opening (51F) and the second via conductor (60S) is formed in the second opening (51S); the first conductive layer (58F), which is made up of the electrolytic plating film 56, the electroless plating film 52 and the metal foil 53, is formed on the first surface of the first insulating layer (50F), and the second conductive layer (58S), which is made up of the electrolytic plating film 56, the electroless plating film 52 and the metal foil 53, is formed on the second surface of the second insulating layer (50S) (refer to FIG. 8C).

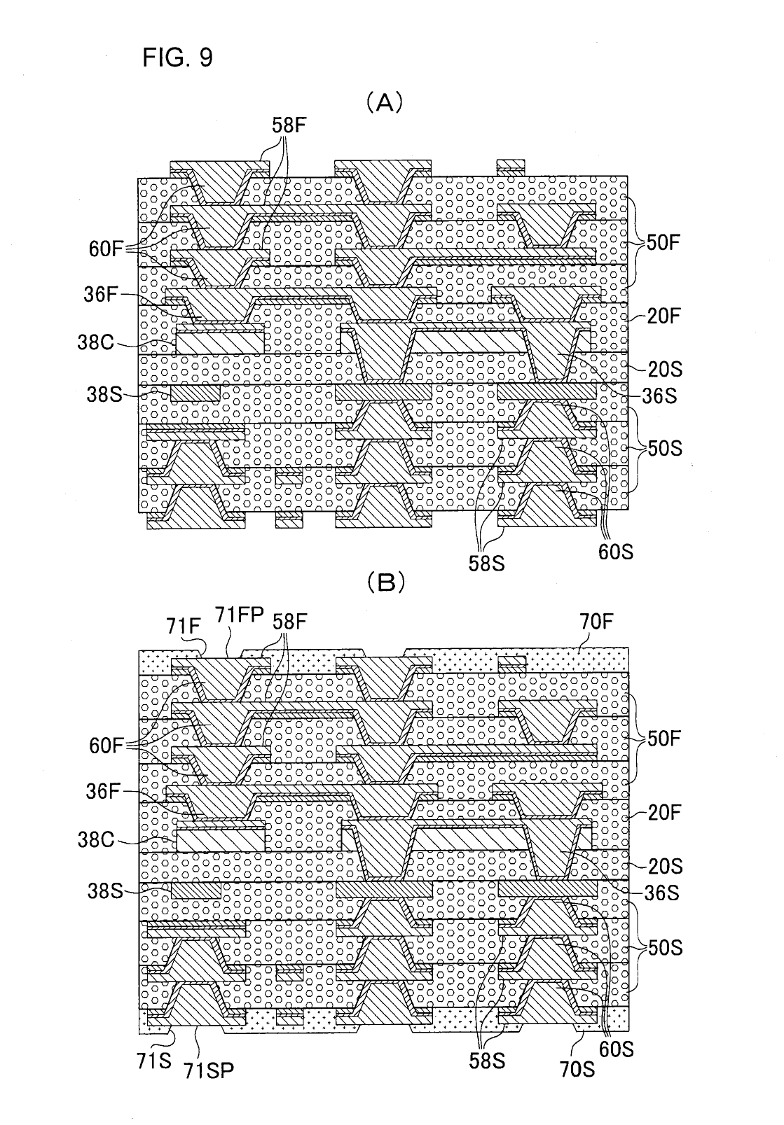

(21) By repeating the processes of FIG. 7A to FIG. 8C, two each layers of the first conductive layer (58F), the insulating layer (50F) with the first via conductor (60S), the second conductive layer (58S), and the second insulating layer (50S) with the second via conductor (60S) are built up (refer to FIG. 9A).

(22) The upper-side solder-resist layer (70F) having the opening (71F) is formed on the uppermost first insulating layer (50F), and the lower-side solder-resist layer (70S) having the opening (71S) is formed on the lowermost second insulating layer (50S) (refer to FIG. 9B). The conductive layers (58F, 58S) exposed from the openings (71F, 71S) and the top surfaces of the via conductors (60F, 60S) function as pads (71FP, 71SP), respectively.

(23) A nickel-plated layer 72 is formed on each of the pads (71FP, 71SP), and a gold-plated layer 74 is further formed on the nickel-plated layer 72 (refer to FIG. 10A).

(24) A solder ball is put in each of the openings (71F, 71S), and is subjected to reflow to form the solder bump (76F) on the upper-side buildup layer and to form the solder bump (76S) on the lower-side buildup layer; the printed wiring board 10 is thereby completed (refer to FIG. 10B).

In the method for manufacturing a printed wiring board according to the first embodiment, an intermediate portion is formed on the support plate 10. Although a single insulating layer is thin, the insulating layer and the conductive layer of the intermediate portion is unlikely to break or crack when transferred or the like. Since the intermediate portion includes two layers of the insulating layers (20F, 20S) and one layer of the thick core conductive layer (38C), the strength of the intermediate portion is enhanced. For this reason, although the intermediate portion is separated from the support plate 10, warping and undulation of the intermediate portion are reduced. The intermediate portion suffers hardly any damage although fabricated and transferred without a support plate, and the manufacturing yield of and the connection reliability on the core substrates and the printed wiring boards become enhanced. An efficient manufacturing process for thin printed wiring boards is achieved. The manufacturing method according to the first embodiment enables the formation of buildup layers without using any assembly jig, and also the formation of fine conductor circuits.

Since employing a core metal structure in which the core conductive layer (38C) is provided in the center of the core substrate 30, the method for manufacturing a printed wiring board according to the first embodiment suppresses warping, and the demand for thinner wiring boards can be met. Because of the structure in which a core substrate is formed on the support plate 10, which is removed later, core substrates having a metal core structure can be manufactured through a simplified process, manufacturing costs are reduced and manufacturing yield is enhanced. Since the core conductive layer (38C) is formed by patterning the core metal layer 26, multiple via lands are arranged in the core conductive layer (38C) to be electrically independent of each other, flexibility in wiring design is enhanced, and a highly integrated wiring board is achieved. Since the core substrate 30 is triple-layered with the core conductive layer (38C), the lower conductive layer (38S) including a lower metal foil, and the upper conductive layer (38F) including an upper metal foil, even though buildup layers (conductive layers) are provided symmetrically on the upper and lower sides of the core substrate 30, a printed wiring board having an odd number of conductive layers is achieved. In the printed wiring board according to the first embodiment, the upper conductive layer (38F) is formed with the electrolytic plating film 44, the electroless plating film 42 and the upper metal foil (22F), and the lower conductive layer (38S) is formed with the lower metal foil (22S), and the thickness of the upper conductive layer (38F) is the same as that of the lower conductive layer (38S). Thus, warping due to a difference in the thicknesses of conductive layers hardly ever occurs.

### Second Embodiment

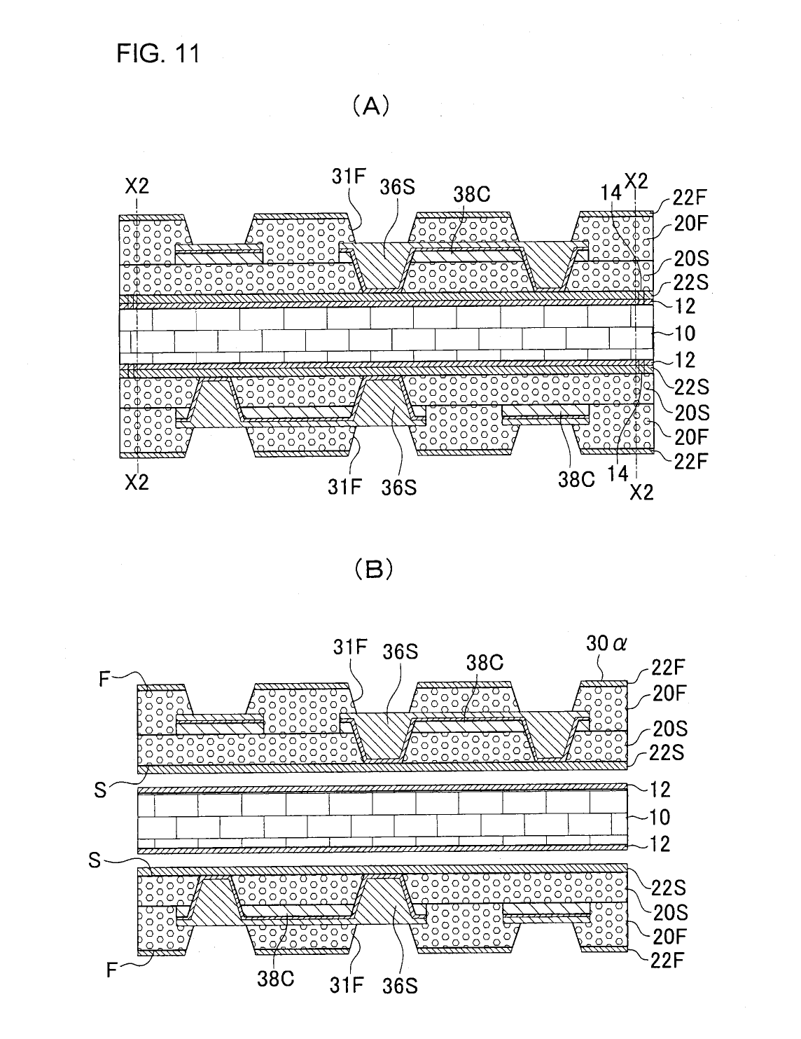

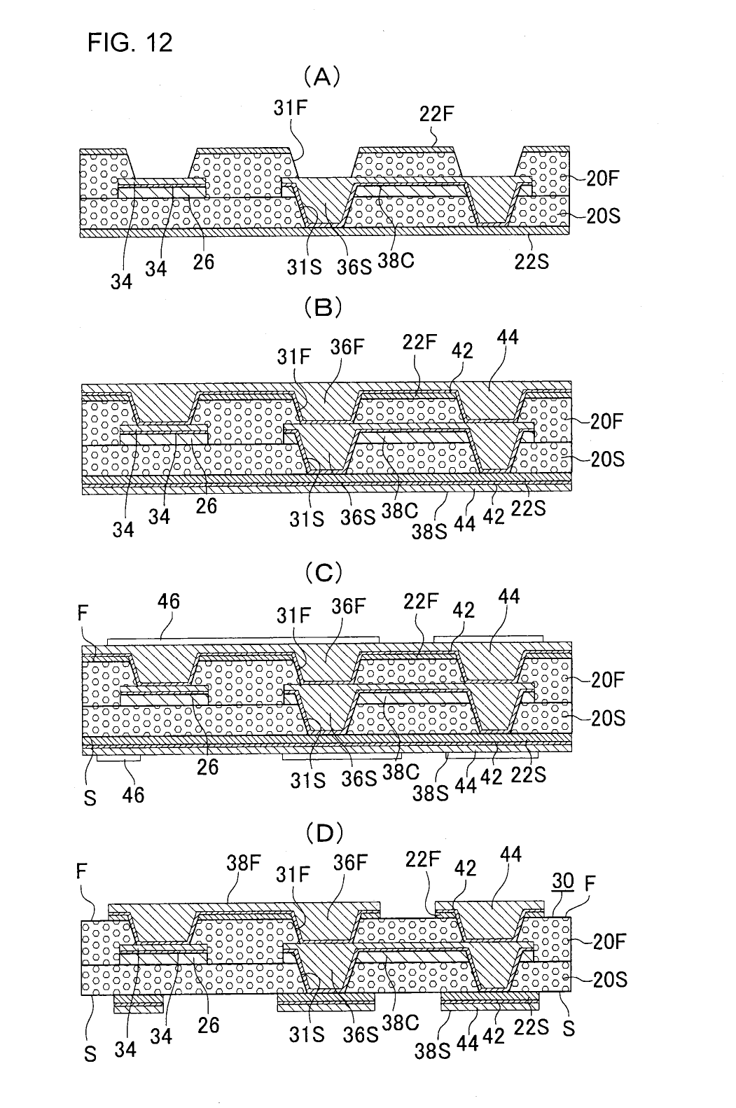

The method for manufacturing a printed wiring board according to the second embodiment is illustrated in FIGS. 11A and 11B and FIGS. 12A, 12B, 12C and 12D.

The manufacturing method of the second embodiment is the same as that of the first embodiment up to the processes illustrated in FIGS. 1A, 1B, 1C to FIGS. 4A, 4B. However, the lower metal foil (22S) is, for example, a copper foil and the thickness is 16 μm, and the upper metal foil (22F) is also, for example, a copper foil, as is the lower metal foil (22S), and the thickness is 12 μm.

After the opening (31F) has been formed in the upper insulating layer (20F) (refer to FIG. 11A), intermediate portions sandwiching the support plate are cut along lines (X2-X2) in FIG. 11A. The cut line is inside the fixing portion 14. The intermediate portion (30α) is separated from the support plate 10 (refer to FIG. 11B, FIG. 12A).

The electroless plating film 42 is formed on the upper metal foil (22F), on the inner wall of the upper opening (31F) and on the lower metal foil (22S), and the electrolytic plating film 44 is formed on the electroless plating film 42 by rendering the electroless plating film 42 to be a seed layer. The upper opening (31F) is filled with the electrolytic plating film 44, and the electrolytic plating film 44 is provided on the electroless plating film 42 formed on the upper metal foil (22F) and the lower metal foil (22S) (refer to FIG. 12B).

On the first-surface (F) side electrolytic plating film 44 and also on the second-surface (S) side lower metal foil (22S), an etching resist 46 having a predetermined pattern is formed (refer to FIG. 12C).

The electrolytic plating film 44, the electroless plating film 42 and the upper metal foil (22F) in the area on the first-surface (F) side where the etching resist 46 is not formed, along with the electrolytic plating film 44, the electroless plating film 42 and the lower metal foil (22S) in the area on the second-surface (S) side where the etching resist 46 is not formed, are removed by etching, and the etching resists 46 are removed. Accordingly, the upper conductive layer (38F), which is made up of the electrolytic plating film 44, the electroless plating film 42 and the upper metal foil (22F), is formed on the first surface (F), while the lower conductive layer (38S), which is made up of the electrolytic plating film 44, the electroless plating film 42 and the lower metal foil (22S), is also formed on the second surface (S). The core substrate 30 is thereby completed (refer to FIG. 12D). The description as to following processes is omitted because the processes are identical to the process in the first embodiment described above by referring FIGS. 7A, 7B, 7C to FIGS. 10A, 10B.

In the printed wiring board according to the second embodiment, the upper conductive layer (38F) is formed with the electrolytic plating film 44, the electroless plating film 42 and the upper metal foil (22F), and the lower conductive layer (38S) is formed with the electrolytic plating film 44, the electroless plating film 42 and the lower metal foil (22S). The thickness of the upper conductive layer (38F) is the same as that of the lower conductive layer (38S) so that warping due to a difference in the thicknesses of conductive layers hardly ever occurs.

### Third Embodiment

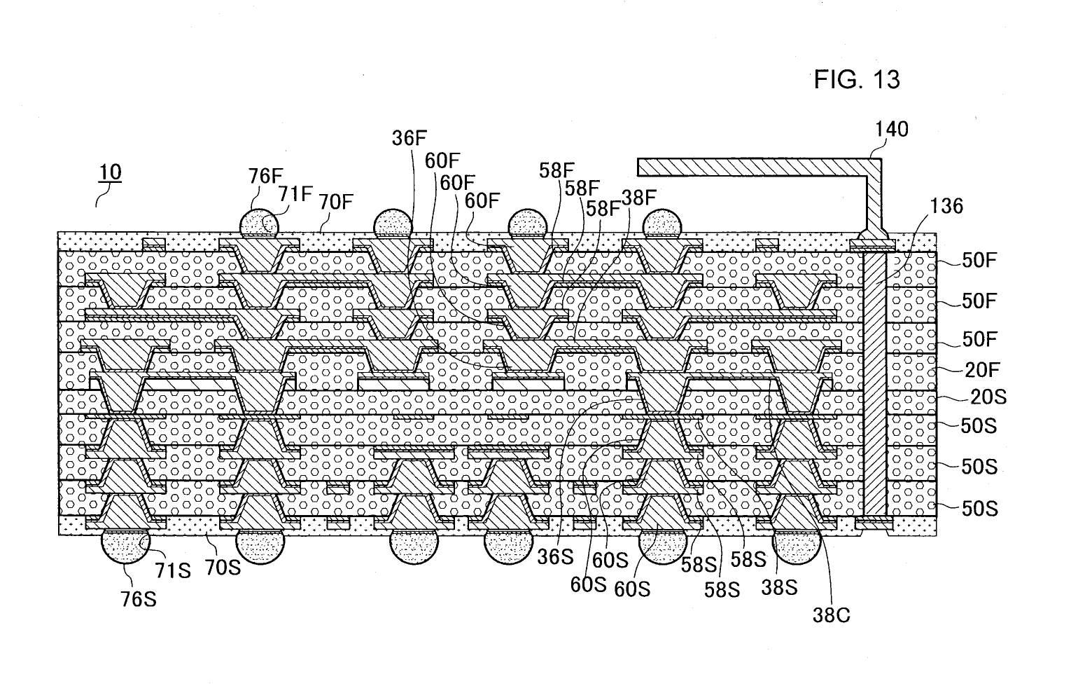

FIG. 13 illustrates a cross-sectional view of a printed wiring board according to the third embodiment.

In the third embodiment, a through-hole conductor 136 penetrating through the printed wiring board is formed, and a heat sink 140 formed in the shape of an “L” is attached to the through-hole conductor 136. The heat sink 140 is in contact with an upper portion of a semiconductor device (not illustrated). The printed wiring board of the third embodiment effectively dissipates the heat, which is generated in the semiconductor device, to the lower side of the printed wiring board by means of the heat sink 140 and the through-hole conductor 136.

As electronic devices are becoming thinner, the thickness of printed wiring boards to be built therein is reduced. A reduction in the thickness of a printed wiring board, however, causes a decrease in the rigidity of an insulating layer, and the insulating layer tends to warp.

A manufacturing process for a metal-core printed wiring board is complicated, the manufacturing costs incurred are significant, and manufacturing yield is difficult to increase. Furthermore, the core metal plate can be used only as a planar conductor.

According to an embodiment of the present invention, a printed wiring board is manufactured by a simplified process and is provided with multiple via lands electrically independent of each other, and another embodiment of the present invention is a method for manufacturing such a printed wiring board.

A method for manufacturing a printed wiring board according to an embodiment of the present invention includes: forming a lower metal foil on at least one side of a support plate; forming a lower insulating layer on the lower metal foil; laminating a core metal layer on the lower insulating layer and forming a core conductive layer by patterning the core metal layer; forming an upper insulating layer on the core conductive layer and lower insulating layer; laminating an upper metal foil on the upper insulating layer; by removing the support plate, forming a core substrate having the lower insulating layer and upper insulating layer; and on the core substrate, forming a buildup layer with an insulating layer and a conductive layer. In such a printed wiring board, the core metal layer is set to be thicker than any of the lower metal foil and the upper metal foil.

A printed wiring board according to an embodiment of the invention includes a core substrate that is formed with a core conductive layer, an upper insulating layer and an upper conductive layer which are formed on an upper surface of the core conductive layer, a lower insulating layer and a lower conductive layer which are formed on a lower surface of the core conductive layer, an upper via conductor which is formed in the upper insulating layer and connects the core conductive layer and the upper conductive layer, and a lower via conductor which is formed in the lower insulating layer and connects the core conductive layer and the lower conductive layer. On the core substrate of the printed wiring board, a buildup layer is formed with an insulating layer and a conductive layer. In such a printed wiring board, the core conductive layer is set to be thicker than any of the lower conductive layer and the upper conductive layer.

A method for manufacturing a printed wiring board according to an embodiment of the invention employs a metal-core structure having a core metal layer in the center of the core substrate, and the rigidity of the core metal layer suppresses warping and the demand for thinner wiring boards is satisfied. A core substrate is formed on a support plate, which is removed later, forming a core substrate having a metal core structure is simplified, manufacturing costs are reduced and manufacturing yield is enhanced. The core conductive layer is formed by patterning the core metal layer, multiple via lands are arranged on the core conductive layer to be electrically independent of each other, flexibility in wiring design is enhanced, and a highly integrated wiring board is achieved. The core substrate is triple-layered with the core conductive layer, the lower conductive layer including a lower metal foil, and the upper conductive layer including an upper metal foil, even though buildup layers (conductive layers) are provided symmetrically on the upper and lower sides of the core substrate, a printed wiring board having an odd number of conductive layers is achieved.

A metal core structure having a core metal layer in the center of the core substrate is employed in the printed wiring board according to an embodiment of the invention, the rigidity of the core metal layer suppresses warping and the demand for thinner wiring boards can be met. Multiple via lands, being electrically independent of each other, can be arranged in the core conductive layer, flexibility in wiring design is enhanced, and packing density can also be enhanced. The core substrate is triple-layered with the core conductive layer, the lower conductive layer and the upper conductive layer, even though buildup layers (conductive layers) are provided symmetrically on the upper and lower sides of the core substrate, a printed wiring board having an odd number of conductive layers is achieved.

Obviously, numerous modifications and variations of the present invention are possible in light of the above teachings. It is therefore to be understood that within the scope of the appended claims, the invention may be practiced otherwise than as specifically described herein.

What is claimed is:

1. A method for manufacturing a printed wiring board, comprising:
fixing a lower metal foil on a support plate;
forming a lower insulating layer on the lower metal foil;
laminating a core metal layer on the lower insulating layer;
patterning the core metal layer such that the core metal layer is formed into a core conductive layer;
forming an upper insulating layer on the core conductive layer and lower insulating layer;
laminating an upper metal foil on the upper insulating layer;
removing the support plate from the lower metal foil such that a core substrate comprising the lower metal foil, the lower insulating layer, the core conductive layer, the upper insulating layer and the upper metal foil is formed; and
forming on the core substrate a buildup layer comprising an insulating layer and a conductive layer,
wherein the core metal layer has a thickness which is set to be greater than a thickness of the lower metal foil and a thickness of the upper metal foil.

2. The method for manufacturing a printed wiring board according to claim 1, further comprising:
forming a via opening portion through the lower insulating layer; and
forming a via conductor comprising plating material in the via opening formed in the lower insulating layer,
wherein the core metal layer is patterned after the forming of the via conductor.

3. The method for manufacturing a printed wiring board according to claim 1, further comprising:
forming a via opening portion through the upper insulating layer;
forming a via conductor comprising plating material in the via opening formed in the upper insulating layer;
patterning the upper metal foil such that the upper metal foil is formed into an upper conductive layer.

4. The method for manufacturing a printed wiring board according to claim 1, further comprising patterning the lower metal foil after the removing of the support plate such that the lower metal foil is formed into a lower conductive layer.

5. The method for manufacturing a printed wiring board according to claim 1, further comprising:
forming a plated layer on the lower metal foil after the removing of the support plate;
forming a plated layer on the upper metal foil after the removing of the support plate;
patterning the lower metal foil and the plated layer formed on the lower metal foil such that the lower metal foil and the plated layer formed on the lower metal foil are formed into a lower conductive layer; and
patterning the upper metal foil and the plated layer formed on the upper metal foil such that the upper metal foil and the plated layer formed on the upper metal foil are formed into an upper conductive layer.

6. The method for manufacturing a printed wiring board according to claim 1, further comprising:
forming a plated layer on the upper metal foil before the removing of the support plate; and
patterning the upper metal foil and the plated layer formed on the upper metal foil after the removing of the support plate such that the upper metal foil and the plated layer formed on the upper metal foil are formed into an upper conductive layer.

7. The method for manufacturing a printed wiring board according to claim 1, further comprising:
forming a plated layer on the upper metal foil before the removing of the support plate;
patterning the upper metal foil and the plated layer formed on the upper metal foil after the removing of the support plate such that the upper metal foil and the plated layer formed on the upper metal foil are formed into an upper conductive layer;
forming a plated layer on the lower metal foil after the removing of the support plate; and
patterning the lower metal foil and the plated layer formed on the lower metal foil such that the lower metal foil and the plated layer formed on the lower metal foil are formed into a lower conductive layer.

8. The method for manufacturing a printed wiring board according to claim 5, wherein the lower metal foil forming the lower conductive layer has a thickness which is greater than a thickness of the upper metal foil forming the upper conductive layer.

9. The method for manufacturing a printed wiring board according to claim 5, wherein the lower conductive layer and the upper conductive layer are formed such that thicknesses of the lower conductive layer and the upper conductive layer are substantially same, and the lower metal foil forming the lower conductive layer has a thickness which is greater than a thickness of the upper metal foil forming the upper conductive layer.

10. The method for manufacturing a printed wiring board according to claim 1, further comprising:
forming a via opening portion through the upper insulating layer;
forming an upper via conductor comprising plating material in the via opening formed in the upper insulating layer;
forming a via opening portion through the lower insulating layer; and
forming a lower via conductor comprising plating material in the via opening formed in the lower insulating layer,
wherein the upper via conductor has a tapered shape, the lower via conductor has a tapered shape, and the tapered shape of the upper via conductor and the tapered shape of the lower via conductor are formed to taper in a same direction.

11. A printed wiring board, comprising:
a core substrate; and
a buildup layer formed on the core substrate and comprising an insulating layer and a conductive layer,
wherein the core substrate includes a core conductive layer, an upper insulating layer formed on an upper surface of the core conductive layer, an upper conductive layer formed on the upper insulating layer, a lower insulating layer formed on a lower surface of the core conductive layer, a lower conductive layer formed on the lower insulating layer, an upper via conductor formed in the upper insulating layer and connecting the core conductive layer and the upper conductive layer, and a lower via conductor formed in the lower insulating layer and connecting the core conductive layer and the lower conductive layer, and the core conductive layer has a thickness which is greater than a thickness of the lower conductive layer and a thickness of the upper conductive layer.

12. The printed wiring board according to claim 11, wherein the upper via conductor has a tapered shape, the lower via conductor has a tapered shape, and the tapered shape of the upper via conductor and the tapered shape of the lower via conductor are tapered in a same direction.

13. The printed wiring board according to claim 11, wherein the lower conductive layer and the upper conductive layer have thicknesses which are substantially same, and the lower conductive layer includes a lower metal foil having a thickness which is greater than a thickness of an upper metal foil in the upper conductive layer.

14. The printed wiring board according to claim 11, wherein the lower via conductor comprises plating material filling a via opening portion formed through the lower insulating layer.

15. The printed wiring board according to claim 11, wherein the upper via conductor comprises plating material filling a via opening portion formed through the upper insulating layer.

16. The printed wiring board according to claim 11, wherein the lower conductive layer includes a lower metal foil.

17. The printed wiring board according to claim 11, wherein the lower conductive layer includes a lower metal foil and a plated layer formed on the lower metal foil, and the upper conductive layer includes an upper metal foil and a plated layer formed on the upper metal foil.

18. The printed wiring board according to claim 17, wherein the lower conductive layer and the upper conductive layer are formed such that thicknesses of the lower conductive layer and the upper conductive layer are substantially same, and the lower metal foil forming the lower conductive layer has a thickness which is greater than a thickness of the upper metal foil forming the upper conductive layer.

19. The printed wiring board according to claim 17, wherein the lower metal foil forming the lower conductive layer has a thickness which is greater than a thickness of the upper metal foil forming the upper conductive layer.

20. The method for manufacturing a printed wiring board according to claim 17, wherein the lower conductive layer and the upper conductive layer are formed such that thicknesses of the lower conductive layer and the upper conductive layer are substantially same.
